(19) United States
(12) Patent Application Publication
(10) Pub. No.: US 2009/0167346 A1
(43) Pub. Date: Jul. 2, 2009

(54) RECONFIGURABLE CIRCUIT, CONFIGURATION METHOD AND PROGRAM

(75) Inventor: Yukihiro SASAGAWA, Kyoto (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION

(21) Appl. No.: 12/342,451

(22) Filed: Dec. 23, 2008

(30) Foreign Application Priority Data
Dec. 28, 2007 (JP) 2007-338792

(51) Int. Cl. H03K 19/173

(52) U.S. Cl. 326/38

(57) ABSTRACT

The present invention is intended to provide a reconfigurable circuit, a configuration method and a program capable of significantly shortening the configuration time without increasing the area of the chip of the circuit. The reconfigurable circuit equipped with a configuration chain having multiple serial connection registers, comprises first connecting means for connecting the registers inside a first serial connection register and the registers inside a second serial connection register in series, and second connecting means for connecting the registers inside the first serial connection register and the registers inside the second serial connection register in parallel, wherein duplication is made possible by using the second connecting means as bypasses.

### BACKGROUND OF THE INVENTION

The present invention relates to a reconfigurable processor capable of dynamically or statically changing the configuration of a circuit or an arithmetic unit, and more particularly, to a reconfigurable circuit, a configuration method using this reconfigurable circuit and a program for performing the configuration of the reconfigurable circuit.

In a reconfigurable processor capable of dynamically or statically changing the configuration of a circuit or an arithmetic unit, for the purpose of forming the circuit or the arithmetic unit so as to have a desired configuration, it is necessary to use a procedure referred to as “configuration” to set the information of the configuration thereof. Generally speaking, the configuration time required for this configuration is proportional to the degree of freedom and the size of the configuration, thereby becoming long as the configuration becomes complicated and large in size just as in recent years.

As a method for performing configuration, for example, a first method is available in which data is input and supplied to serial connection registers connected to the setting memories of a reconfigurable processor (for example, refer to the specification of U.S. Pat. No. 5,394,031). Although this first method is advantageous in that data can be supplied to the setting memories distributed to the entire processor using a few input terminals, since data is supplied serially, there is a problem that the configuration time is long.

Furthermore, as a method for shortening the configuration time, for example, a second method is available in which configuration input is processed in parallel to raise the rate of data transfer (for example, refer to the specification of U.S. Pat. No. 6,714,044). In this second method, as shown in FIG. 14, a serial connection register 1 for supplying configuration data is divided into multiple segments, and data input lines corresponding to the respective segments are provided in parallel to raise the rate of data transfer and shorten the configuration time.

In the case of the second method in which data input is processed in parallel, there is a problem that the area of the chip increases due to the increase in the number of input/output lines of the chip. Since an object of using the reconfigurable processor is essentially to reduce the size of the circuit for attaining multiple functions, the increase in the area of the chip is not desirable.

### SUMMARY OF THE INVENTION

In consideration of the above-mentioned problems, the present invention is characterized in that bypasses (second connecting means and third connecting means in embodiments described later) are provided to supply data in a direction of crossing a configuration chain having multiple serial connection registers for supplying configuration data, and that the bypasses are used to perform duplication processing.

A reconfigurable circuit according to the present invention having a configuration chain in which multiple serial connection registers are connected in series, comprises:

first connecting means for connecting in series multiple registers inside each of the multiple serial connection registers to enable signal transmission,

second connecting means for connecting in parallel the registers inside each of the multiple serial connection registers to the registers inside a serial connection register connected thereto in series to enable signal transmission, and

configuration memories for storing the configuration information of the registers inside the configuration chain. In the reconfigurable circuit according to the present invention configured as described above, the area of the chip is not increased, and the configuration time can be shortened significantly.

A configuration method using the reconfigurable circuit according to the present invention comprises:

a first step of renewing the configuration information of the registers inside one of the multiple serial connection registers using the first connecting means,

a second step of storing the configuration information of the registers inside the serial connection register renewed at the first step into the configuration memories provided for the registers inside the serial connection register,

a third step of duplicating the configuration information stored in the registers inside the serial connection register to the registers inside another serial connection register using the second connecting means, and

a fourth step of storing the configuration information of the registers inside the other serial connection register duplicated at the third step into the configuration memories provided for the registers inside the other serial connection register. In the configuration method according to the present invention configured as described above, the area of the chip is not increased, and the configuration time can be shortened significantly.

A program for performing the configuration of the reconfigurable circuit according to the present invention for causing a computer to perform the configuration of the reconfigurable circuit equipped with a configuration chain having multiple serial connection registers, has:

operands for providing configuration information to duplicate the configuration information stored in the registers inside one of the multiple serial connection registers constituting the configuration chain to the registers inside another serial connection register constituting the configuration chain and connected in parallel with the registers of the one serial connection register. By the use of the program according to the present invention configured as described above, the area of the chip is not increased, and the configuration time can be shortened significantly.

With the present invention, the data of the configuration chain having multiple serial connection registers is duplicated in the crossing direction. Therefore, the configuration data covering and corresponding to all the configuration targets can be securely supplied, and the configuration time can be shortened significantly without raising the data transfer rate of data input.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 is a view showing the structure of a configuration chain according to a first embodiment of the present invention;

FIG. 2 is a view showing a configuration procedure that uses the configuration of the configuration chain according to the first embodiment shown in FIG. 1;

FIG. 3 is a view showing the structure of a configuration chain according to a second embodiment of the present invention;

FIG. 4 is a view showing a configuration procedure that uses the configuration of the configuration chain according to the second embodiment shown in FIG. 3;

FIG. 5 is a view showing a configuration procedure that uses the configuration of a configuration chain according to a third second embodiment of the present invention;

FIG. 6 shows a generalized bit string to be compressed and used in a fourth embodiment according to the present invention;

FIG. 7 is a view showing the structure of a configuration chain according to a fourth embodiment of the present invention;

FIG. 8 is a view showing a correspondence between the form of repetition regularity and the operation of the configuration chain according to the fourth embodiment;

FIG. 9 is a view showing another correspondence between the form of repetition regularity and the operation of the configuration chain according to the fourth embodiment;

FIG. 10 is a view showing a read back procedure in which the configuration of a configuration chain according to a fifth embodiment of the present invention is used;

FIG. 11 is a view showing a configuration example of a configuration according to a sixth embodiment of the present invention;

FIG. 12 is a view showing examples of basic instructions according to the sixth embodiment;

FIG. 13 is a view showing examples in the case that the basic instructions according to the sixth embodiment are applied to the first to fifth embodiments;

FIG. 14 is a view showing a conventional configuration method;

FIG. 15 is a view showing the procedure of the conventional configuration method; and

FIG. 16 is a view showing the procedure of the conventional read back method.

It will be recognized that some or all of the Figures are schematic representations for purposes of illustration and do not necessarily depict the actual relative sizes or locations of the elements shown.

### DETAILED DESCRIPTION OF THE PREFERRED EMBODIMENTS

Best modes for attaining a reconfigurable circuit, a configuration method using the reconfigurable circuit and a program for performing the configuration of the reconfigurable circuit according to the present invention will be described below in detail referring to the accompanying drawings.

### First Embodiment

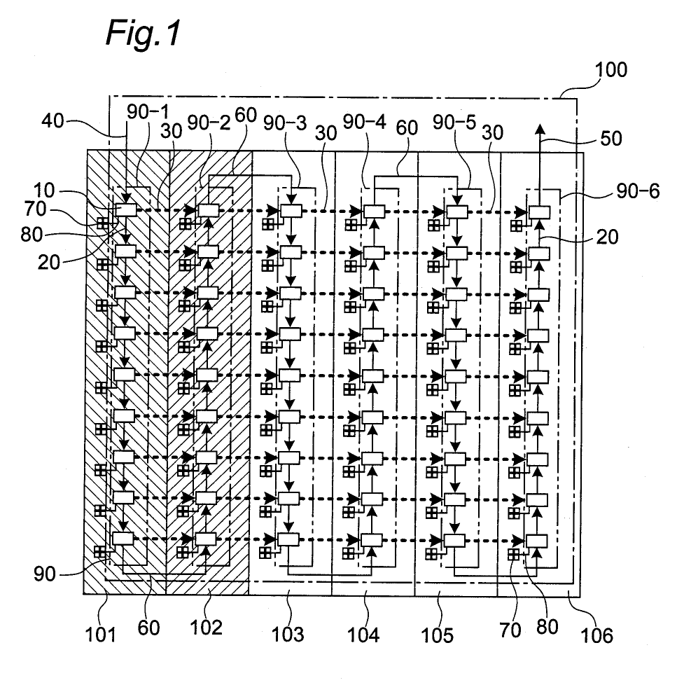

FIG. 1 is a view showing the structure of a configuration chain 100 constituting the reconfigurable circuit of a reconfigurable processor according to a first embodiment of the present invention. The configuration chain 100 comprises multiple serial connection registers 90 (90-1, 90-2, 90-3, . . . ), data lines 60 connecting these serial connection registers 90 in series, bypasses 30 connecting the multiple registers 10 of each serial connection register 90 to the multiple registers 10 of a serial connection register 90 adjacent thereto in parallel, an input terminal 40 for inputting data, and an output terminal 50 for outputting data. As shown in FIG. 1, in the configuration chain 100, the respective serial connection registers 90 are disposed so as to meander via the data lines 60, and the serial connection registers 90 adjacent to each other are disposed in parallel. Hence, the bypasses 30 are provided so that data crosses each serial connection register 90 of the configuration chain 100. In each serial connection register 90, all the multiple registers 10 thereof are connected linearly in series via data lines 20. The serial connection registers 90 respectively belong to domains 101, 102, 103, 104, 105 and 106 serving as configuration targets. Each register 10 of the serial connection register 90 is connected to a setting memory 70 existing inside each domain via a signal line 80. Although only one configuration chain 100 is shown in FIG. 1, multiple configuration chains may also be provided inside the reconfigurable processor. Furthermore, although a specific number of the serial connection registers 90 and a specific number of the registers 10 in the serial connection register 90 are shown in FIG. 1, the numbers in the present invention are not limited to the numbers shown in the figure but may be determined appropriately. Moreover, in the first embodiment, the data lines 20 correspond to first connecting means, and the bypasses 30 correspond to second connecting means.

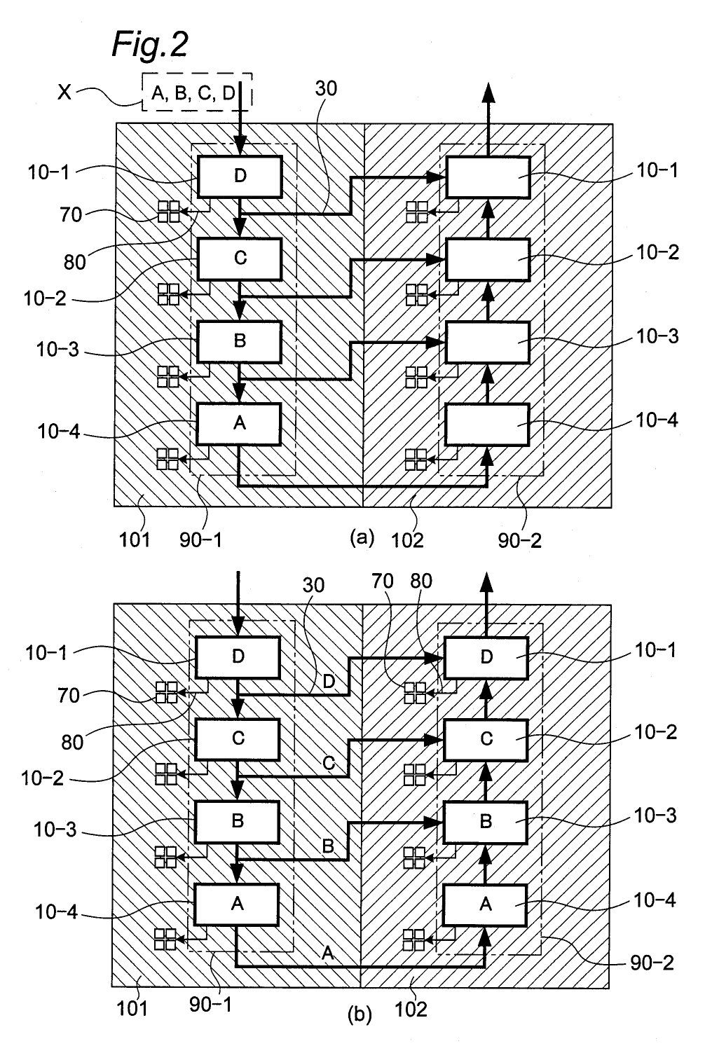

FIG. 2 is a view showing the procedure of a configuration method that uses the configuration of the configuration chain 100 shown in FIG. 1. The procedure in FIG. 2 is illustrated by focusing on the domains 101 and 102 shown in FIG. 1.

The configuration procedure according to the first embodiment shown in FIG. 2 comprises the following three steps.

Step 1: data X (exemplified by “A, B, C and D” in FIG. 2) is shift-input to the serial connection register 90-1 contained in the domain 101 serving as a configuration target. When it is assumed that the number of the stages in all the serial connection registers of the configuration chain 100 is N (N: a positive integer) and that the number of the stages in each serial connection register 90 is M (M: a positive integer), M is sufficiently smaller than N (M<<N), and the number of cycles required for the shift input is M. Although a case in which M is four is shown as an example in FIG. 2, the number is not limited to this number. The contents of the respective registers 10-1, 10-2, 10-3 and 104 of the serial connection register 90-1 are renewed (shifted) to “D”, “C”, “B” and “A” by the shift input.

Step 2: the renewal results (“D”, “C”, “B” and “A”) of the respective registers 10-1, 10-2, 10-3 and 104 are stored into the respective setting memories 70 via the signal lines 80. In parallel with this storage operation, the contents of the renewal results (“D”, “C”, “B” and “A”) of the respective registers 10-1, 10-2, 10-3 and 104 are duplicated and transferred to the adjacent serial connection register 90-2 via the bypasses 30. By this duplication and transfer, the contents of the respective registers 10-1, 10-2, 10-3 and 104 of the serial connection register 90-2 are renewed as shown in the part (b) of FIG. 2. The number of cycles required for the data storage into the setting memories 70 and the duplication and transfer to the adjacent serial connection register is one.

Step 3: the renewal results of the respective registers 10-1, 10-2, 10-3 and 10-4 of the serial connection register 90-2 are stored into the setting memories 70 via the signal lines 80. The number of cycles required for the data storage into the setting memories 70 is one.

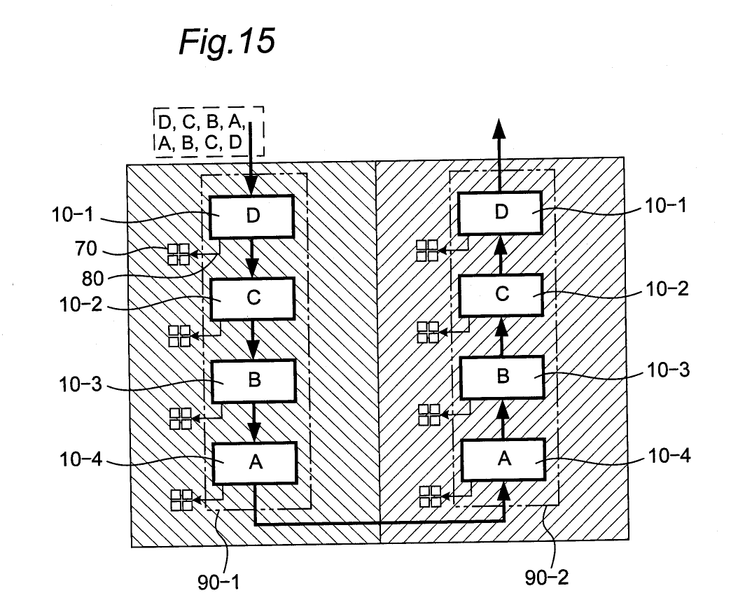

As described above, in the configuration method according to the first embodiment, the number of cycles required for step 1 to step 3 is M+2. In the case that configuration is performed similarly using the conventional first method described in the specification of the above-mentioned U.S. Pat. No. 5,394,031, the contents of the serial connection register 90-1 and the serial connection register 90-2 connected thereto in series are renewed only by shift input as shown in FIG. 15. Hence, in the conventional first method, the shift input at step 1 requires N cycles, and the data storage into the setting memories 70 at step 2 requires one cycle, whereby the number of cycles required is N+1.

M+2<<N+1 is established because of the relationship of M<<N. It can thus be understood that, with the configuration method according to the first embodiment, the storage into the setting memories 70 can be attained in fewer cycles than with the conventional method.

As described above, with the procedure of the configuration method according to the first embodiment of the present invention, the input repetition data (“A”, “B”, “C” and “D”) of the serial connection register 90-1 is duplicated to the adjacent serial connection register 90-2 via the bypasses 30 and stored into the setting memories 70. Hence, the configuration for all the domains can be completed without shift-inputting the data to all the serial connection registers.

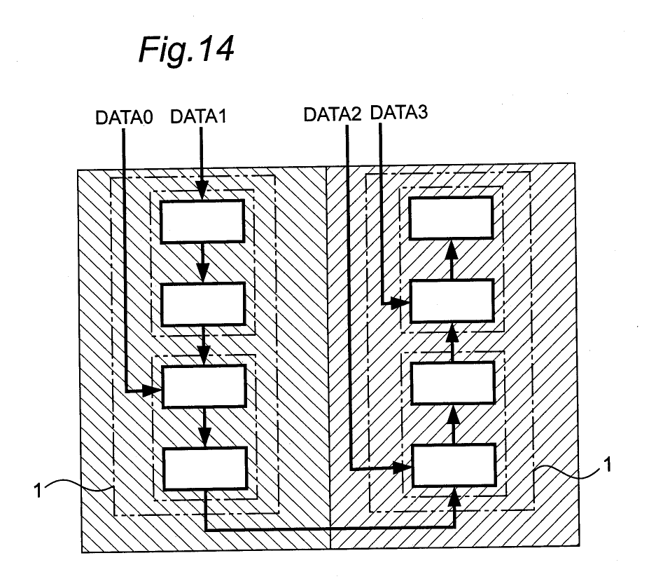

In the case that the conventional second method described in the specification of the above-mentioned U.S. Pat. No. 6,714,044, there is a problem that data input lines increase as shown in FIG. 14. However, with the configuration method according to the first embodiment, data input lines do not increase as shown in FIG. 2, and the configuration time can be shortened significantly.

Since the reconfigurable processor is generally configured so that the same arithmetic elements are disposed regularly, the setting memories 70 are also disposed regularly in a similar way. In the present invention, it is important to utilize this regularity to efficiently perform data supply for the configuration. The first embodiment according to the present invention is characterized in that the configuration chains 100 are disposed in a direction along a constant direction (in the vertical direction (the up-down direction in FIG. 1) in the first embodiment) and that the bypasses 30 are disposed along a direction (in the horizontal direction (the left-right direction in FIG. 1) in the first embodiment) different from the disposition direction of the configuration chains 100. With this characteristic, bypasses utilizing the regular disposition in the reconfigurable processor can be attained, and it is possible to obtain an effect of significantly shortening the configuration time.

### Second Embodiment

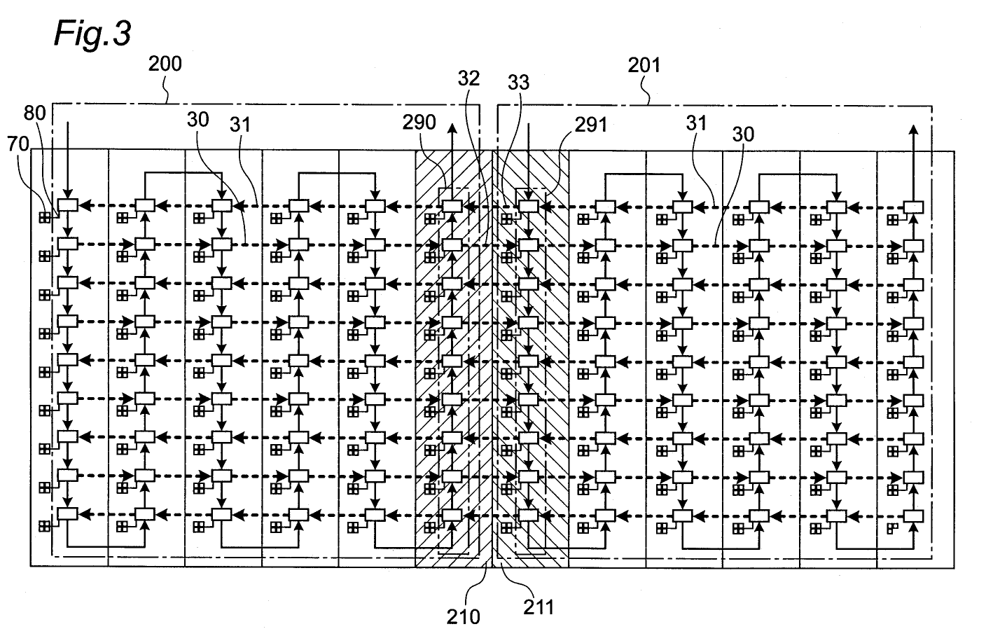

Next, a configuration chain constituting the reconfigurable circuit of a reconfigurable processor according to a second embodiment of the present invention will be described below. FIG. 3 is a view showing the structure of the configuration chain according to the second embodiment. The configuration chain according to the second embodiment is another form of the configuration chain 100 according to the first embodiment shown in FIG. 1 and has two configuration chains 200 and 201.

In the second embodiment, in addition to first bypasses 30 similar to the bypasses according to the first embodiment shown in FIG. 1, second bypasses 31 are provided to perform duplication processing in a direction opposite to that of the first bypasses 30. Furthermore, in the configuration of the second embodiment, it is desirable that third bypasses 32 and fourth bypasses 33 for performing duplication processing should be provided between the two configuration chains 200 and 201. Although a case in which the two configuration chains 200 and 201 are provided is described in FIG. 3, more configuration chains may be provided inside the reconfigurable processor. Moreover, although the configuration in which the first bypasses 30 and the second bypasses 31 are disposed alternately and the third bypasses 32 and the fourth bypasses 33 are disposed alternately is described in FIG. 3, the present invention is not limited to this order of disposition. Even if another order of disposition is used, the effect of the present invention is obtained similarly. In the second embodiment, the first bypasses 30, the second bypasses 31, the third bypasses 32 and the fourth bypasses 33 correspond to second connecting means.

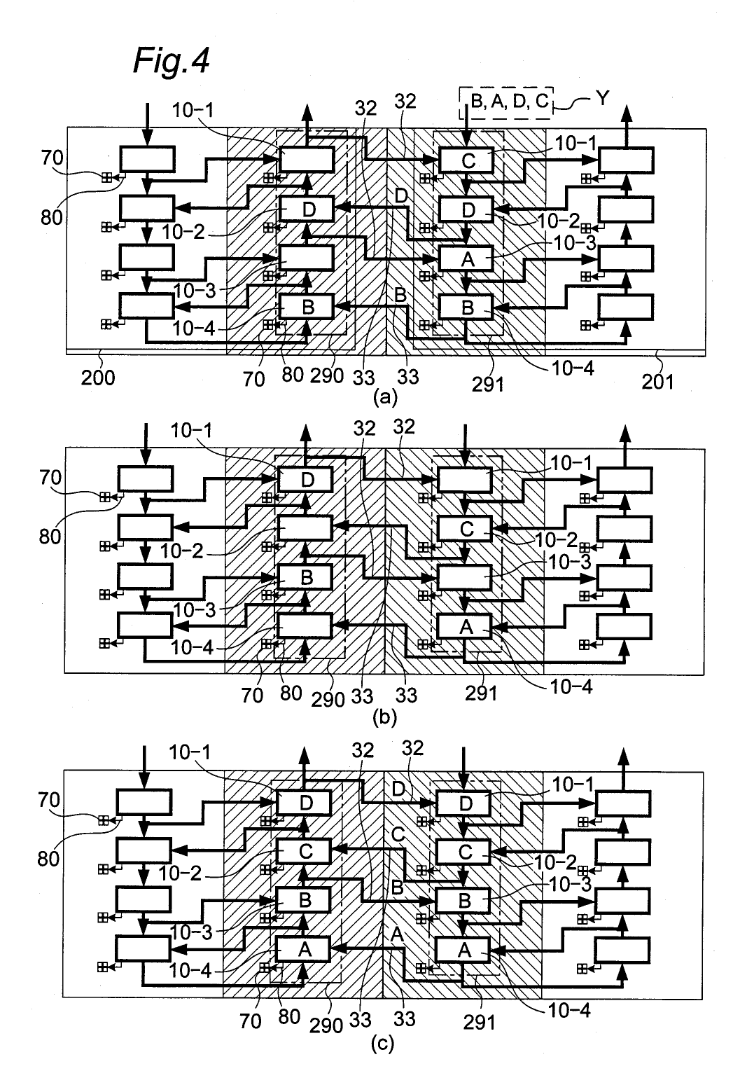

FIG. 4 is a view showing the procedure of the configuration method that uses the configuration of the configuration chain according to the second embodiment shown in FIG. 3. The procedure in FIG. 4 is illustrated by focusing on the domains 210 and 211 of the two configuration chains 200 and 201 shown in FIG. 3. The domains 210 and 211 contain serial connection registers 290 and 291, respectively, and the serial connection registers are connected to each other so that duplication processing can be performed using the third bypasses 32 and the fourth bypasses 33.

The configuration procedure according to the second embodiment shown in FIG. 4 comprises the following five steps.

Step 1: data Y (exemplified by “B, A, D and C” in FIG. 4) is shift-input to the serial connection register 291 contained in the domain 211 serving as a configuration target. When it is assumed that the number of the stages in all the serial connection registers of each of the configuration chains 200 and 201 is N (N: a positive integer) and that the number of the stages in each serial connection register is M (M: a positive integer), M is sufficiently smaller than N (M<<N), and the number of cycles required for the shift input is M. Although a case in which M is four is shown as an example in FIG. 4, the number is not limited to this number in the present invention. The contents of the respective registers 10-1, 10-2, 10-3 and 104 of the serial connection register 291 are renewed to “C”, “D”, “A” and “B” by the shift input.

Step 2: the renewal results (“D” and “B”) of the registers 10-2 and 10-4 of the serial connection register 291 are duplicated and transferred as the contents of the serial connection register 291 to the serial connection register 290 via the fourth bypasses 33. By this duplication and transfer, the contents of the registers 10-2 and 104 of the serial connection register 290 are renewed to “D” and “B” as shown in the part (a) of FIG. 4. The number of cycles required for the duplication and transfer is one.

Step 3: the respective serial connection registers 290 and 291 are shifted. By this shift, the contents of the serial connection registers 290 and 291 are changed. In other words, the contents of the registers 10-1 and 10-3 of the connection register 290, one of the serial connection registers, become “D” and “B”, and the contents of the registers 10-2 and 10-4 of the other serial connection register 291 become “C” and “A” as shown in the part (b) of FIG. 4. The number of cycles required for this shift is one.

Step 4: the renewal results “C” and “A” of the registers 10-2 and 10-4 of the serial connection register 291 are stored into the respective setting memories 70 via the signal lines 80. Concurrently with this storage operation, the renewal results are duplicated and transferred to the serial connection register 290 via the fourth bypasses 33 as shown in the part (c) of FIG. 4. In a similar way, concurrently with this duplication and transfer, the renewal results “D” and “B” of the registers 10-1 and 10-3 of the serial connection register 290 are stored into the respective setting memories 70 via the signal lines 80. Concurrently with this storage operation, the renewal results are duplicated and transferred to the serial connection register 291 via the third bypasses 32 as shown in the part (c) of FIG. 4.

By the above-mentioned duplication and transfer, the contents of the serial connection registers 290 and 291 are renewed as shown in the part (c) of FIG. 4. The number of cycles required for the duplication and transfer is one.

Step 5: the renewal results of the registers 10-2 and 104 of the serial connection register 290 and the renewal results of the registers 10-1 and 103 of the serial connection register 291 are respectively stored into the setting memories 70 via the signal lines 80. The number of cycles required for the data storage into the setting memories 70 is one.

As described above, in the configuration method according to the second embodiment, the number of cycles required for step 1 to step 5 is M+4. On the other hand, in the case that the conventional first method described in the specification of the above-mentioned U.S. Pat. No. 5,394,031 is used, the contents of the serial connection register 90-1 and the serial connection register 90-2 connected thereto in series are renewed only by shift input as shown in FIG. 15. Hence, in the conventional first method, the shift input at step 1 requires N cycles, and the data storage into the setting memories 70 at step 2 requires one cycle, whereby the number of cycles required is N+1.

M+4<<N+1 is established because of the relationship of M<<N. It can thus be understood that, with the configuration method according to the second embodiment, the storage into the setting memories 70 can be attained in fewer cycles than with the conventional method as an effect similar to that of the first embodiment. Furthermore, in the second embodiment, even in the case of the serial connection register 290 positioned at the end of the configuration chain 200, the duplication and transfer from the adjacent configuration chain 201 can be performed in addition to the effect of the first embodiment. For this reason, the number of cycles required for the duplication and transfer in the second embodiment is reduced significantly in comparison with the first embodiment in which multiple cycles are required for the duplication and transfer to the serial connection register positioned at the end of the configuration chain.

### Third Embodiment

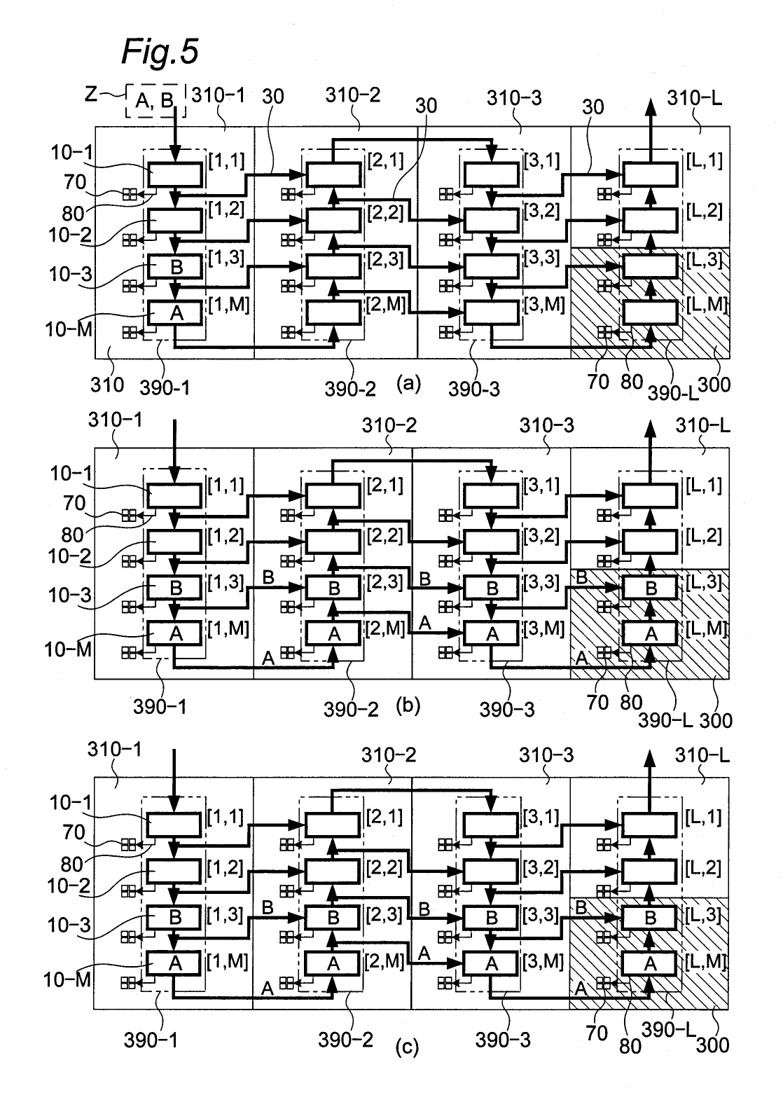

Next, a configuration chain constituting the reconfigurable circuit of a reconfigurable processor according to a third embodiment of the present invention will be described below. FIG. 5 is a view showing the structure of the configuration chain according to the third embodiment.

A dynamic reconfigurable processor requires the so-called partial configuration in which configuration is performed for only a specific circuit or an arithmetic unit. FIG. 5 is a view showing the procedure of the partial configuration according to the third embodiment that uses the structure of the configuration chain shown in FIG. 1.

FIG. 5 shows a case of partial configuration for a specific domain 300 serving as a configuration target. In FIG. 5, coordinates ([1, 1] to [L, M]) are defined for the respective registers of the configuration chain to generally indicate data transfer to the specific domain 300. The maximum value M (M: a positive integer) of the coordinates in the vertical direction is equal to the number M of the stages in the respective serial connection registers 390 (390-1, 390-2, 390-3, . . . ) belonging to the domains 310 (310-1, 310-2, 310-3, . . . ) serving as the respective configuration targets, and the maximum value L (L: a positive integer) of the coordinates in the horizontal direction is equal to the number of the stages in the transfer operation between the serial connection registers 390 via the bypasses 30. Although a case in which M is 4 and L is 4 is shown as examples in FIG. 5, M and L are not to this value but may be set appropriately.

The configuration procedure according to the third embodiment shown in FIG. 5 comprises the following five steps.

Step 1: data Z (exemplified by “A, B” in FIG. 5) is shift-input to the serial connection register 390-1. When it is assumed that the number of the stages in all the serial connection registers of each configuration chain is N and that the number of the stages in the serial connection register 390-1 is M, M is sufficiently smaller than N (M<<N). In addition, the number of cycles required for the shift input is the number of cycles corresponding to the coordinates of the specific domain 300, and the maximum value thereof is not more than M. It is herein assumed that the registers 10-3 and 10-M defined by the coordinates [L, 3] and [L, M] and belonging to the domain 310-L are used as the specific domain 300.

The contents of the registers 10-3 and 10-M of the serial connection register 390-1 are renewed to “B” and “A” by the shift input to the serial connection register 390-1 as shown in the part (a) of FIG. 5.

Step 2: the renewal results of the registers 10-3 and 10-M of the serial connection register 390-1 are transferred to the serial connection registers 390-2, 390-3 and 390-L of the subsequent stages via the bypasses 30. By this transfer, the contents of the serial connection register 390-L containing the specific domain 300 are renewed as shown in the part (b) of FIG. 5. The number of cycles required for the transfer is the number of cycles corresponding to the coordinates of the specific domain 300, and the maximum value thereof is not more than L.

Step 3: the renewal results of the registers 10-3 and 10-M of the serial connection register 390-L are respectively stored into the setting memories 70 via the signal lines 80. The number of cycles required for the data storage into the setting memories 70 is one.

As described above, in the configuration method according to the third embodiment, the number of cycles required for step 1 to step 3 is L+M+1. On the other hand, in the case that the first method described in the specification of the above-mentioned U.S. Pat. No. 5,394,031 is used, the contents of the serial connection register 90-1 and the serial connection register 90-2 connected thereto in series are renewed only by shift input as shown in FIG. 15. Hence, in the conventional first method, the shift input at step 1 requires N cycles, and the data storage into the setting memories 70 at step 2 requires one cycle, whereby the number of cycles required is N+1. FIG. 15 shows a case in which the configuration for the same purpose is performed for the serial connection registers (90-1 and 90-2) being connected only in series using the first method described in the specification of the U.S. Pat. No. 5,394,031.

L+M+1<<N+1 is established because of the relationship of M<<N. It can thus be understood that, with the configuration method according to the third embodiment, the storage into the setting memories can be attained in fewer cycles than with the conventional method as an effect similar to that of the first embodiment. Furthermore, in the third embodiment, even in the case that the specific domain 300 has any coordinates, it can also be understood that the effect of reducing the number of cycles is obtained in addition to the effect of the first embodiment.

By the procedure of the configuration method according to the third embodiment, configuration data (A, B) is transferred via the bypasses 30 and stored into the setting memories 70 connected to the adjacent serial connection register. Hence, configuration can be performed only for a specific circuit or an arithmetic unit without performing shift input to the registers of all the serial connection registers.

### Fourth Embodiment

Next, a configuration chain constituting the reconfigurable circuit of a reconfigurable processor according to a fourth embodiment of the present invention will be described below.

Generally speaking, as a reversible data compression method for bit strings, a method typified by the run-length coding method is available in which a bit string is converted into a form consisting of basic patterns and their repetitions by extracting the repetition regularity thereof.

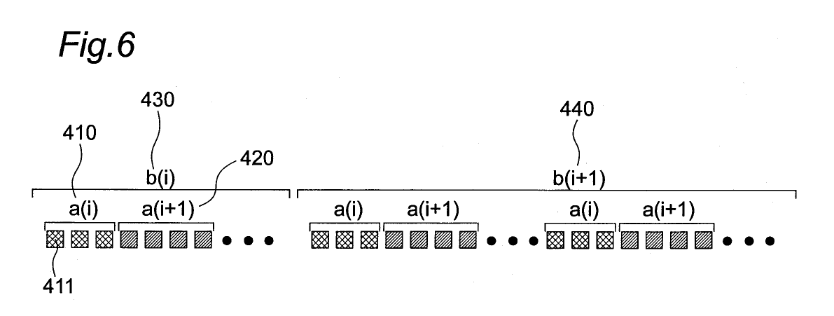

FIG. 6 shows a generalized bit string to be compressed. In FIG. 6, a square 411 indicates a bit representing a given value (0 or 1). This bit string has a group 410 in which a value is repeated a(i) times, a group 420 in which another value is repeated a(i+1) times, and the subsequent groups in which values are repeated similarly. In addition, the string has a group 430 in which a data pattern consisting of a(i), a(i+1), . . . is repeated b(i) times, a group 440 in which the data pattern is repeated b(i+1) times, and the subsequent groups in which the data pattern is repeated similarly.

Data volume compression can be attained for the bit string consisting of these multiple groups by using the basic patterns of the groups 430 and 440 and the forms consisting of the basic patterns of the groups 410 and 420 and their repetitions as configuration data. This compression operation can be attained by compressing the data with configuration data generation software (compiler) using a general data compression algorithm. On the other hand, in the case that the configuration data is restored to the original bit string and stored into the setting memories 70, a mechanism for decompressing the compressed data is required inside the reconfigurable processor. It is desirable that this should be attained while avoiding increase in circuit size due to the use of a dedicated data decompression circuit.

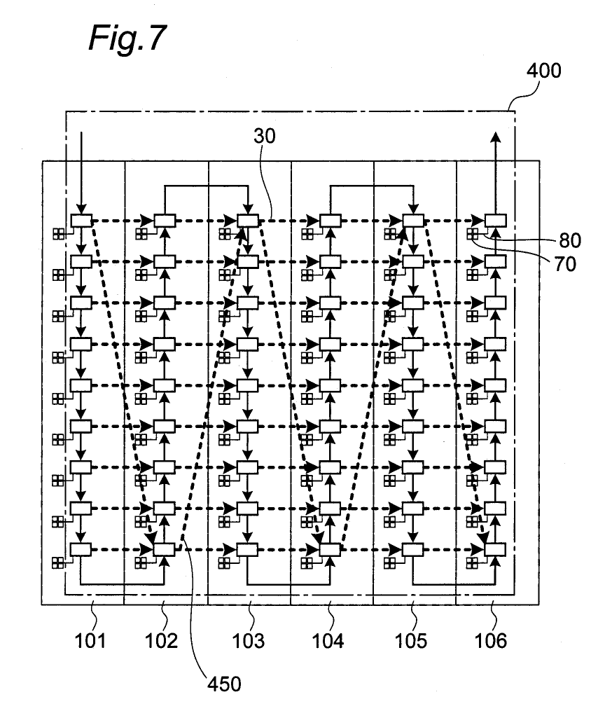

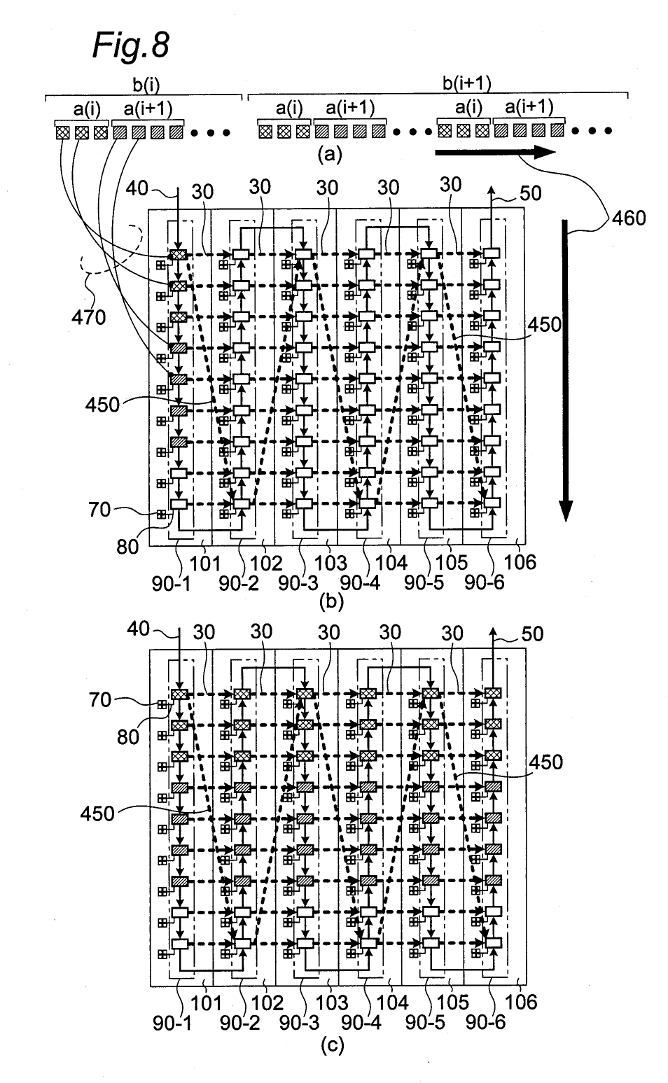

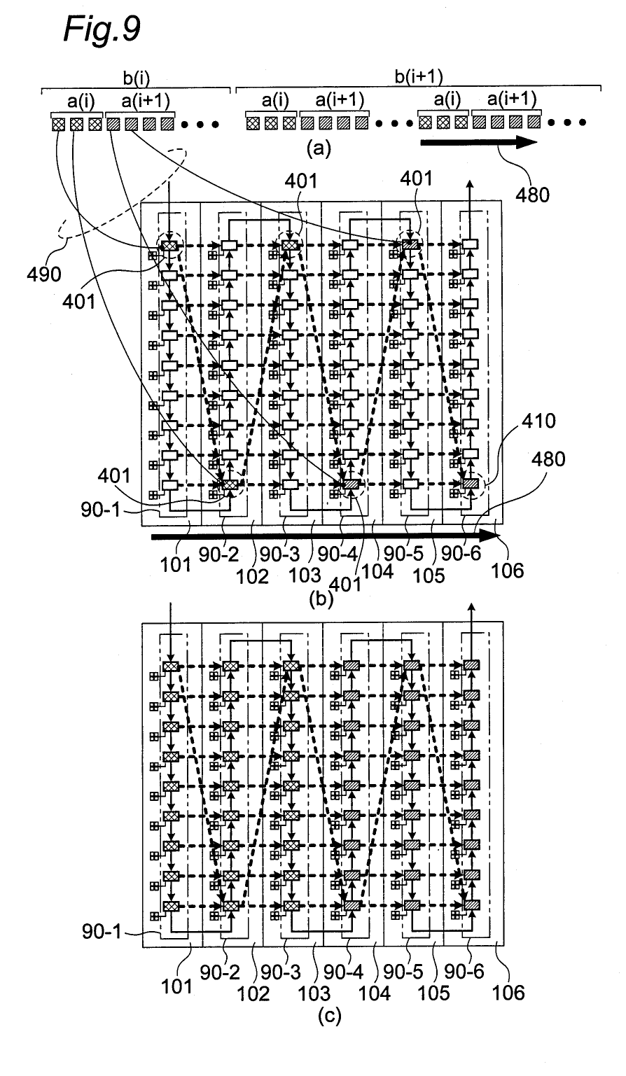

FIG. 7 is a view showing a configuration structure capable of restoring the compressed data in the process of data transfer to the setting memories 70. Although the basic concept of the structure of the configuration chain shown in FIG. 7 is similar to those of the above-mentioned first and second embodiments, bypasses 450 are added as third connecting means in addition to the bypasses 30 to attain restoration conforming to the form of repetition regularity of the compressed data. Although only one configuration chain 400 is shown in FIG. 7, multiple configuration chains may be provided inside the reconfigurable processor. FIGS. 8 and 9 show the correspondence between the form of repetition regularity and the operation of the configuration chain.

FIG. 8 shows configuration operation in the case that the basic patterns (shown in the part (a) of FIG. 8) are set in the vertical direction as indicated by arrow 460. The configuration method according to the fourth embodiment shown in FIG. 8 has steps similar to those of the above-mentioned first embodiment and comprises the following three steps. The part (a) of FIG. 8 shows the configuration data shown in FIG. 6, and the parts (b) and (c) of FIG. 8 show configuration chain operation in the case that the basic patterns are set in the vertical direction.

Step 1: data is shift-input to the serial connection register 90-1. In the serial connection register 90-1, the correspondence between the basic patterns and the renewal contents is indicated using leading lines 470.

Step 2: the contents of the serial connection register 90-1 are sequentially duplicated and transferred to the adjacent serial connection registers (90-2, 90-3, 90-4, . . . ) via the bypasses 30 serving as the second connecting means (see the part (c) of FIG. 8).

Step 3: the renewal results of the serial connection registers are respectively stored into the setting memories 70 via the signal lines 80.

Next, the configuration operation in the case that the basic patterns are set in the horizontal direction will be described below. FIG. 9 shows the configuration operation in the case that the basic patterns are set in the horizontal direction as indicated by arrow 480. The configuration procedure according to the fourth embodiment shown in FIG. 9 comprises the following three steps. The part (a) of FIG. 9 shows the configuration data shown in FIG. 6, and the parts (b) and (c) of FIG. 9 show configuration chain operation in the case that the basic patterns are set in the horizontal direction.

Step 1: a serial connection register formed of registers connected using the bypasses 450 serving as the third connecting means is used as another form of serial connection register 401. Data is shift-input to the serial connection register 401 configured as described above. In the serial connection register 401, the correspondence between the basic patterns and the renewal contents is indicated using leading lines 490 as shown in the parts (a) and (b) of FIG. 9. The serial connection register 401 formed of registers connected using the bypasses 450 comprises the first-stage registers of the serial connection registers (90-1, 90-2, 90-3, 90-4, . . . ).

Step 2: the contents of the serial connection register 401 are duplicated and transferred to the adjacent registers using the connection configuration of the respective serial connection registers (90-1, 90-2, 90-3, 90-4, . . . ). The data flow of the duplication and transfer is similar to that of the shift operation shown in FIG. 8 (see the part (c) of FIG. 9).

Step 3: the renewal results of the respective serial connection registers are stored into the setting memories 70 via the signal lines 80.

As described above, data duplication is possible using the configuration method according to the fourth embodiment by the combination of the operations of the configuration chain 400, regardless of whether the basic patterns are set in the vertical direction (FIG. 8) or in the horizontal direction (FIG. 9). In other words, the configuration operation and the data decompression operation can be attained simultaneously.

Furthermore, compression can also be attained even in a configuration having a large data volume using the configuration method according to the fourth embodiment. Moreover, since the amount of data transfer is reduced by compression, the configuration time can be reduced without increasing data input/output lines.

Still further, the fourth embodiment is characterized in that, as shown in FIG. 7, the configuration chains 400 are disposed in a constant direction (in the vertical direction in the case of the configuration shown in FIG. 1), and the bypasses 30 and the bypasses 450 are disposed along directions (in the horizontal direction and oblique directions in the case of the configuration shown in FIG. 7) different from the disposition direction of the configuration chains 400. With this characteristic according to the fourth embodiment, bypasses utilizing the regular disposition in the reconfigurable processor can be attained, and it is possible to obtain a configuration structure having a data decompression function.

### Fifth Embodiment

Next, a configuration chain constituting the reconfigurable circuit of a reconfigurable processor according to a fifth embodiment of the present invention will be described below.

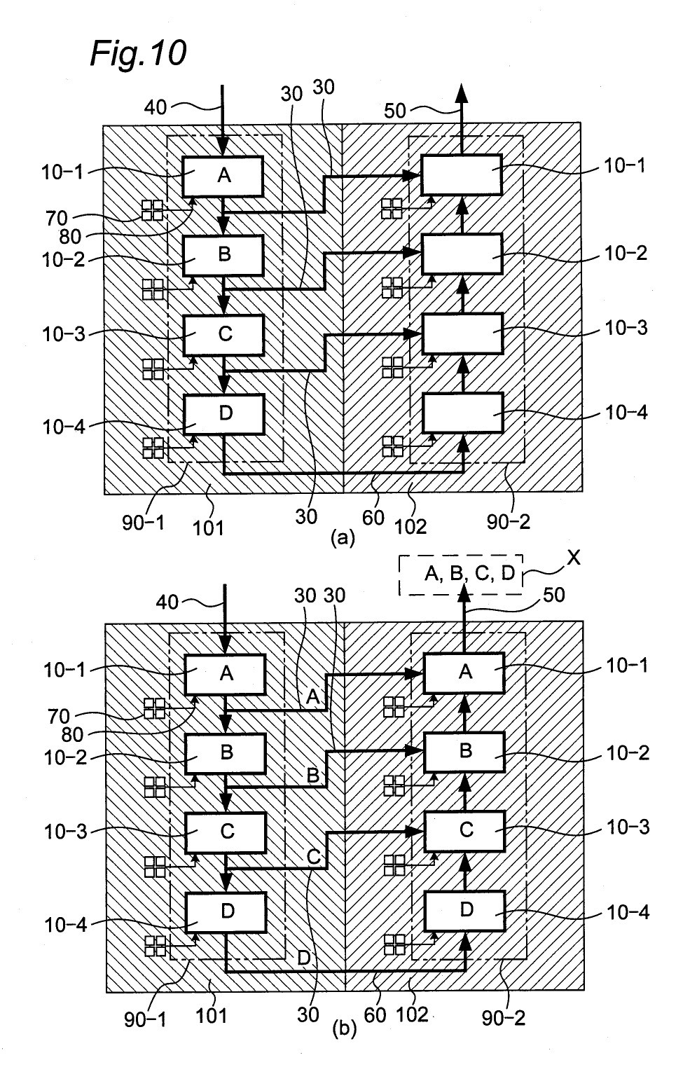

The reconfigurable processor may occasionally require an operation referred to as the so-called read back in which the data stored in the setting memories 70 is read via the configuration chains to perform debugging, LSI tests or the like. FIG. 10 is a view showing a read back procedure in which the structure of the configuration chain shown in FIG. 1 is used in the fifth embodiment of the present invention. The structure in FIG. 1 is shown by focusing on a case in which the data stored in the setting memories belonging to the domain 101 is read. The procedure of the read back method shown in FIG. 10 comprises the following three steps.

Step 1: the contents of the setting memories 70 are stored into the serial connection register 90-1 via the signal lines 80. By this storage operation, the contents of the registers 10-1, 10-2, 10-3 and 10-4 of the serial connection register 90-1 are renewed as shown in the part (a) of FIG. 10. The number of cycles required for the data storage is one.

Step 2: as shown in the part (b) of FIG. 10, the contents of the serial connection register 90-1 are duplicated and transferred to the adjacent serial connection register 90-2 via the bypasses 30 and the bypasses 60. By this duplication and transfer, the contents of the registers 10-1, 10-2, 10-3 and 10-4 of the serial connection register 90-2 are renewed as shown in the part (b) of FIG. 10. The number of cycles required for the duplication and transfer is one.

Step 3: the contents of the serial connection register 90-2 are shift-output as data X (described as “A, B, C and D” in FIG. 10). When it is assumed that the number of the stages in all the serial connection registers of the configuration chain is N (N: a positive integer) and that the number of the stages in each serial connection register is M (M: a positive integer), M is sufficiently smaller than N (M<<N), and the number of cycles required for the shift output is M.

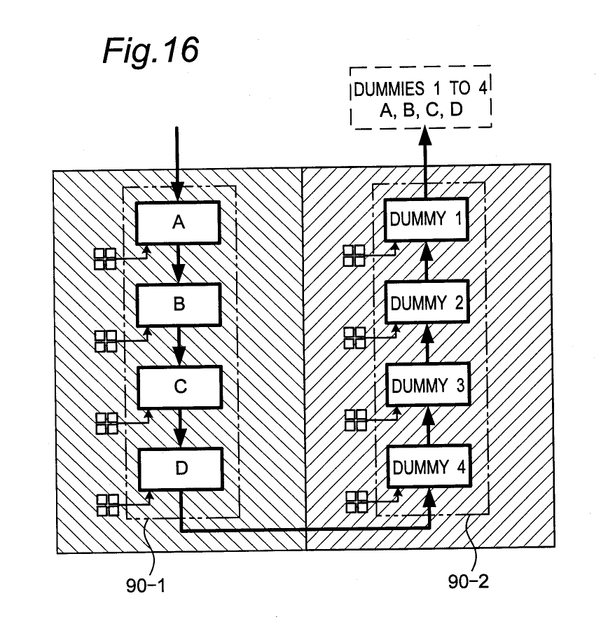

As described above, in the read back method according to the fifth embodiment, the number of cycles required for step 1 to step 3 is M+2. On the other hand, in the case that the first method described in the specification of the above-mentioned U.S. Pat. No. 5,394,031 is used, the data of the serial connection register 90-1 is read by only the shift output as shown in FIG. 16. The data reading to the setting memories 70 at step 1 requires one cycle, and the shift output at step 2 requires N cycles, whereby the number of cycles required is N+1. FIG. 16 shows a case in which read back operation achieving the same purpose is performed for the serial connection registers (90-1 and 90-2) connected only in series using the first method described in the specification of the above-mentioned U.S. Pat. No. 5,394,031. Hence, with the first method, the contents of the adjacent serial connection register 90-2 are output as dummies (dummies 1, 2, 3 and 4) as shown in FIG. 16.

M+2<<N+1 is established because of the relationship of M<<N. It can thus be understood that, with the present invention, the read back operation can be attained in fewer cycles than with the conventional method.

As described above, in the fifth embodiment, the data stored in the setting memories 70 is transferred via the bypasses 30 and the data lines 60 and output to the output terminal 50. Hence, the read back operation can be attained without shift-outputting all the contents of the serial connection registers 90-1 and 90-2.

### Sixth Embodiment

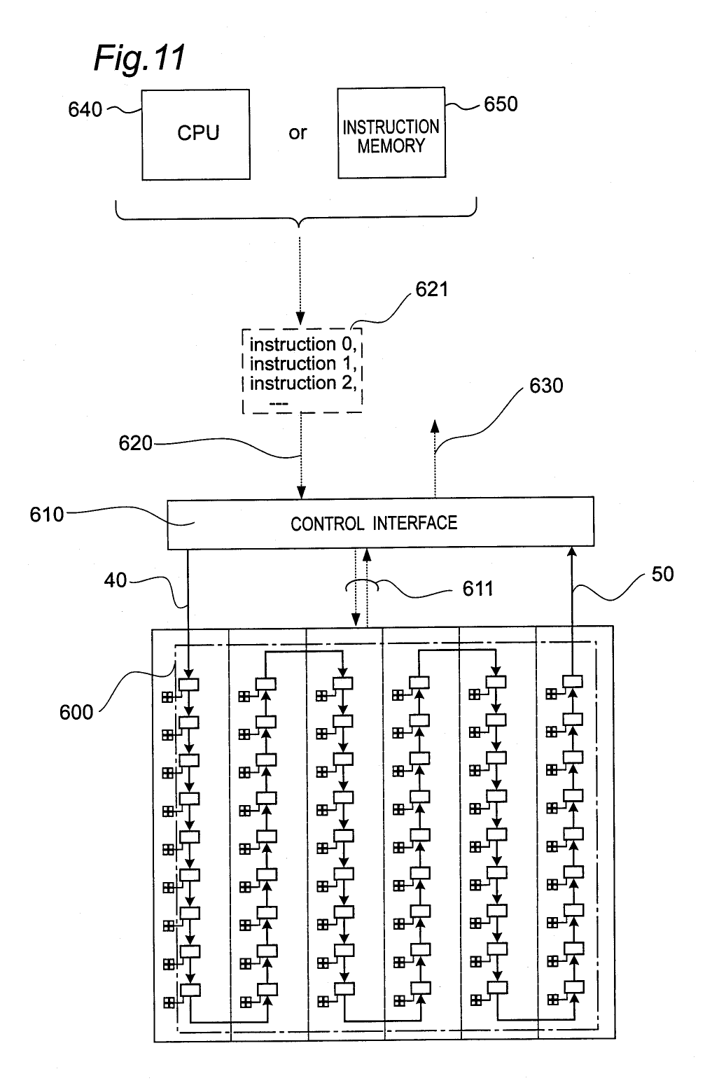

As a method for efficiently attaining the procedures for the configuration methods described in the above-mentioned first to fifth embodiments, a method is available in which the configuration operation of the reconfigurable processor is written as a program containing multiple configuration instructions. FIG. 11 shows a configuration example for embodying this method and is a view showing a configuration example of a configuration circuit according to a sixth embodiment of the present invention. The configuration chain 100, 200 or 400 shown in the above-mentioned FIG. 1, 3 or 7 is used as a configuration chain 600 in the configuration example shown in FIG. 11. The configuration chain 600 is connected to a control interface 610 via control terminals 611 through which control signals are input/output, an input terminal 40 through which data is input, and an output terminal 50 through which data is output. The control interface 610 has a control input terminal 620 and a control output terminal 630. The control input terminal 620 is connected to a CPU 640 or an instruction memory 650, and instructions 621 (for example, instruction 0, instruction 1, instruction 2, . . . ) are input to the control interface 610.

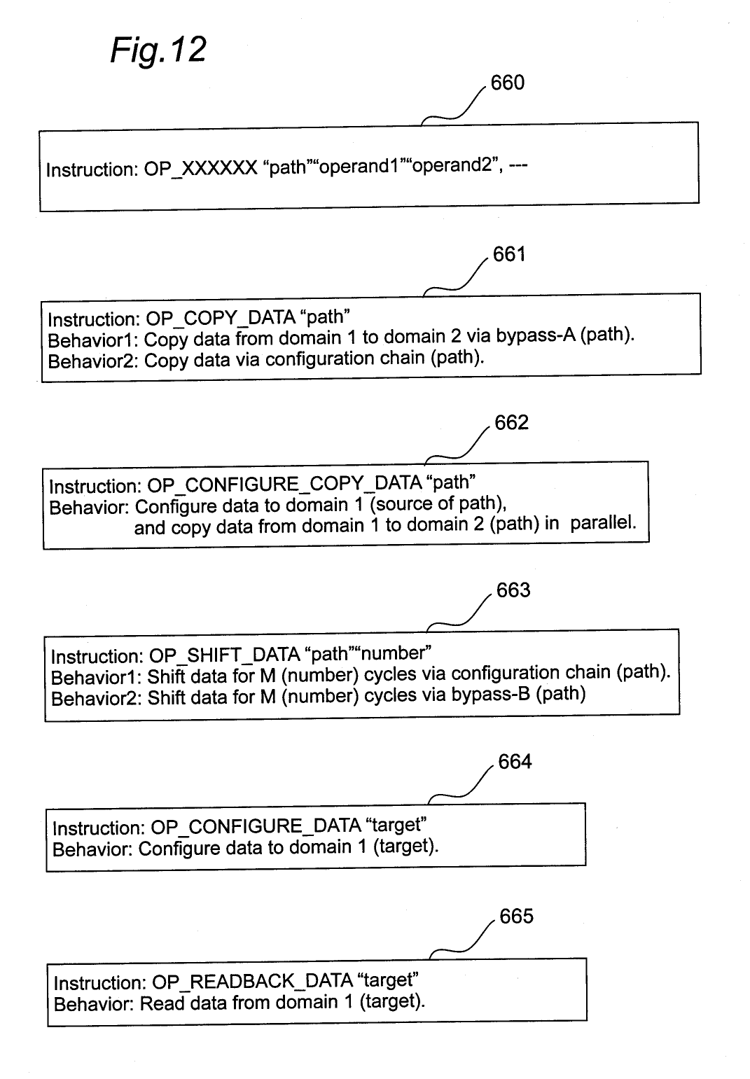

A bypass designation function is required as a function of the instructions 621 to attain the procedures for the configuration methods described in the above-mentioned first to fifth embodiments. FIG. 12 shows specific examples of the instructions 621. In FIG. 12, an example of an operand for designating a bypass is represented by numeral 660, and examples of basic instructions for attaining the configuration procedures are represented by numerals 661 to 665. It is desirable that an operand “path” should be provided as in the example of the operand 660 shown in FIG. 12. Furthermore, it is desirable that the following basic instructions are provided to attain the configuration procedures.

Instruction 661: a duplication instruction by which data is duplicated using the path designated in the operand “path”

Path example 1) from the serial connection register 90-1 via the bypasses 30 to the adjacent serial connection register 90-2 in the first embodiment shown in FIG. 2

Path example 2) between the registers via the connections inside the serial connection register 90-1 in the fourth embodiment shown in FIG. 8

Instruction 662: a configuration/duplication parallel-execution instruction by which the data of the serial connection register corresponding to the start point of the path designated in the operand “path” is stored into the setting memories 70 via the signal lines 80 and the data is concurrently duplicated using the path designated in the operand “path”

Path example) from the serial connection register 90-1 via the bypasses 30 to the adjacent serial connection register 90-2 in the first embodiment shown in FIG. 2

Instruction 663: a shift instruction by which data is shifted using the path designated in the operand “path” and the shift is repeated by the number of times designated in an operand “number”

Path example 1) between the registers via the connections inside the serial connection register 90-1 and the serial connection register 90-2 in the first embodiment shown in FIG. 2

Path example 2) between the registers inside the serial connection register 401 via the bypasses 450 in the fourth embodiment shown in FIG. 9

Instruction 664: a configuration instruction by which the contents of the serial connection register belonging to the domain designated in an operand “target” are stored into the setting memories 70 via the signal lines 80

Instruction 665: a read back instruction by which the contents of the setting memories 70 belonging to the domain designated in an operand “target” are stored into the serial connection register via the signal lines 80

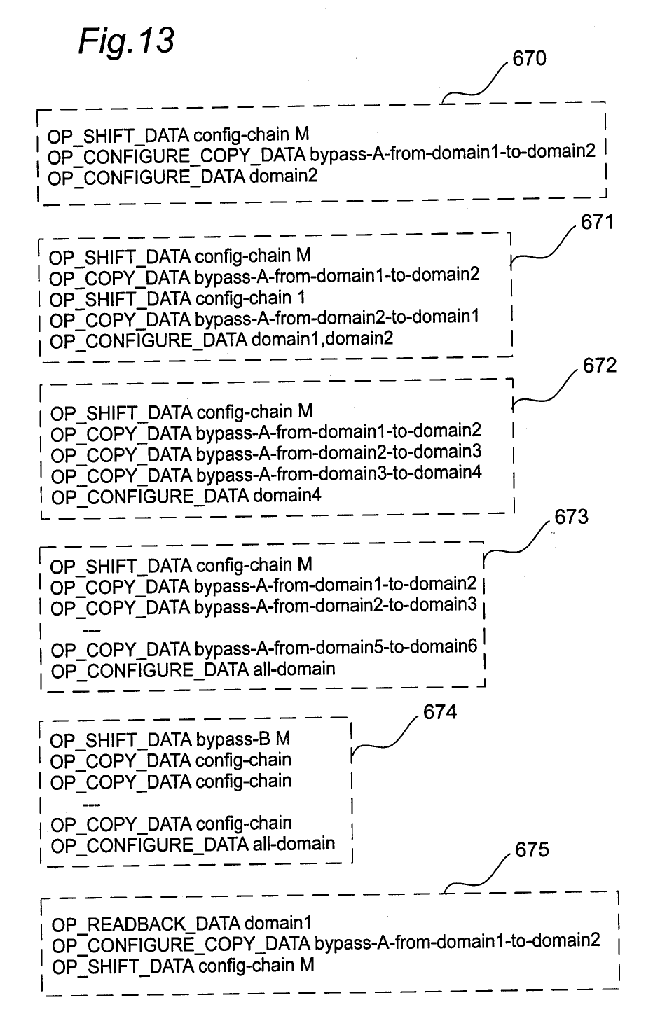

The configuration methods according to the first to fifth embodiments are performed using the above-mentioned basic instructions 661 to 665 in the configuration example of the sixth embodiment shown in FIG. 11. FIG. 13 shows specific examples of the instructions 621 attained in the sixth embodiment. The above-mentioned first to fifth embodiments are respectively attained as described below using the above-mentioned basic instructions 661 to 665.

The first embodiment shown in FIG. 2: shown using an instruction sequence 670 in FIG. 13. The steps and the instructions in the first embodiment correspond to each other as described below. The domains 101 and 102 correspond to domain1 and domain2, respectively, and the bypass 30 corresponds to bypass-A.

| | |
|---|---|
| Step 1: | OP_SHIFT_DATA config-chain M |
| Step 2: | OP_CONFIGURE_COPY_DATA bypass-A-from-domain1- |
| | to-domain2 |
| Step 3: | OP_CONFIGURE_DATA domain2 |

The second embodiment shown in FIG. 4: shown using an instruction sequence 671 in FIG. 13. The steps and the instructions in the second embodiment correspond to each other as described below. The domains 210 and 211 correspond to domain1 and domain2, respectively, and the bypasses 30, 32 and 33 correspond to bypass-A.

| | |
|---|---|
| Step 1: | OP_SHIFT_DATA config-chain M |
| Step 2: | OP_COPY_DATA bypass-A-from-domain1-to- |
| | domain2 |
| Step 3: | OP_SHIFT_DATA config-chain 1 |
| Step 4: | OP_COPY_DATA bypass-A-from-domain2-to- |
| | domain1 |
| Step 5: | OP_CONFIGURE_DATA domain1, domain2 |

The third embodiment shown in FIG. 5: shown using an instruction sequence 672 in FIG. 13. The steps and the instructions in the third embodiment correspond to each other as described below. The domains 310-1, 310-2, 310-3 and 310-4 correspond to domain1, domain2, domain3 and domain4, respectively, and the bypass 30 corresponds to bypass-A.

| | |
|---|---|
| Step 1: | OP_SHIFT_DATA config-chain M |
| Step 2: | OP_COPY_DATA bypass-A-from-domain1-to-domain2 |
| | OP_COPY_DATA bypass-A-from-domain2-to-domain3 |
| | OP_COPY_DATA bypass-A-from-domain3-to-domain4 |
| Step 3: | OP_CONFIGURE_DATA domain4 |

The fourth embodiment shown in FIG. 8: shown using an instruction sequence 673 in FIG. 13. The steps and the instructions in the fourth embodiment shown in FIG. 8 correspond to each other as described below. The domains 101, 102, 103, . . . correspond to domain1, domain2, domain3, . . . , respectively, and the bypass 30 corresponds to bypass-A.

| | |
|---|---|
| Step 1: | OP_SHIFT_DATA config-chain M |
| Step 2: | OP_COPY_DATA bypass-A-from-domain1-to-domain2 |
| | OP_COPY_DATA bypass-A-from-domain2-to-domain3 |

- - -

| | |
|---|---|
| | OP_COPY_DATA bypass-A-from-domain5-to-domain6 |
| Step 3: | OP_CONFIGURE_DATA all-domain |

The fourth embodiment shown in FIG. 9: shown using an instruction sequence 674 in FIG. 13. The steps and the instructions in the fourth embodiment shown in FIG. 9 correspond to each other as described below. The bypass 450 corresponds to bypass-B.

| | |
|---|---|
| Step 1: | OP_SHIFT_DATA bypass-B M |
| Step 2: | OP_COPY_DATA config-chain |
| | OP_COPY_DATA config-chain |

- - -

| | |
|---|---|
| | OP_COPY_DATA config-chain |
| Step 3: | OP_CONFIGURE_DATA all-domain |

The fifth embodiment shown in FIG. 10: shown using an instruction sequence 675 in FIG. 13. The steps and the instructions in the fifth embodiment correspond to each other as described below. The domains 101 and 102 correspond to domain1 and domain2, respectively, and the bypass 30 corresponds to bypass-A.

| | |
|---|---|
| Step 1: | OP_READBACK_DATA domain1 |
| Step 2: | OP_CONFIGURE_COPY_DATA bypass-A-from- |
| | domain1-to-domain2 |
| Step 3: | OP_SHIFT_DATA config-chain M |

As described above, it can be understood that the configuration procedures described in the respective embodiments can be attained using the basic instructions shown in FIG. 12. The configuration operation of the reconfigurable processor can be described as a program comprising multiple instructions using the configuration example of the sixth embodiment according to the present invention.

The CPU 640 or the instruction memory 650 according to the sixth embodiment may be configured so as to be mounted inside the same chip as that of the reconfigurable processor. In the case of such a configuration, it is possible to further produce a new effect capable of attaining fast data transfer using the wiring inside the chip.

Since the present invention can shorten the configuration time while suppressing increase in chip input/output lines, the reduction of the configuration time can be attained even in the case that the configuration is made large in size. Furthermore, the present invention is applicable to dynamic configurations in which short-time partial configuration is required during operation and thereby being useful for reconfigurable processors.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

What is claimed is:

1. A reconfigurable circuit having a configuration chain in which multiple serial connection registers are connected in series, comprising:
first connecting means for connecting in series multiple registers inside each of said multiple serial connection registers to enable signal transmission,
second connecting means for connecting in parallel the registers inside each of said multiple serial connection registers to the registers inside a serial connection register connected thereto in series to enable signal transmission, and
configuration memories for storing the configuration information of the registers inside said configuration chain.

2. The reconfigurable circuit according to claim 1, wherein
all the registers constituting each of said multiple serial connection registers are disposed linearly, and
a serial connection register adjacent to said multiple serial connection registers are disposed in parallel therewith.

3. The reconfigurable circuit according to claim 1, wherein said second connecting means is configured so as to supply the configuration information of all the registers constituting one of said multiple serial connection registers to all the registers constituting another serial connection register.

4. The reconfigurable circuit according to claim 1, wherein said second connecting means is configured so as to supply the configuration information of part of the registers constituting one of said multiple serial connection registers to part of the registers constituting another serial connection register and to supply the configuration information of part of the remaining registers constituting said other serial connection register to part of the remaining registers constituting said one serial connection register.

5. The reconfigurable circuit according to claim 1, further comprising third connecting means configured so as to supply the configuration information of the first stage register of the registers constituting one of said multiple serial connection registers to the first stage register of the registers constituting another serial connection register.

6. The reconfigurable circuit according to claim 1, wherein
said reconfigurable circuit has at least a first serial connection register and a second serial connection register,
said first connecting means connect the registers inside said first serial connection register in series and also connect the registers inside said second serial connection register in series and
the second connecting means is configured so as to connect the registers inside said first serial connection register to the registers inside said second serial connection register in parallel.

7. The reconfigurable circuit according to claim 6, wherein
said first serial connection register has a first register and a second register,
said second serial connection register has a third register and a fourth register, and
said second connecting means is configured so as to supply the configuration information of said first register to said third register and to supply the configuration information of said fourth register to said second register.

8. The reconfigurable circuit according to claim 6, wherein
said reconfigurable circuit has third connecting means,
said first serial connection register has a first register,
said second serial connection register has a second register and a third register,
said second connecting means are used to connect said first register to said second register, and
said third connecting means are used to connect said first register to said third register.

9. The reconfigurable circuit according to claim 6, wherein
said reconfigurable circuit has a third serial connection register and third connecting means,
said first serial connection register has a first register,
said second serial connection register has a second register,
said third serial connection register has a third register,
said second connecting means is used to connect said first register and said second register, and
said third connecting means is use to connect said first register and said third register.

10. The reconfigurable circuit according to claim 6, wherein in the case that the registers constituting said configuration chain are arranged linearly and configuration information is input thereto, third connecting means are provided to connect the registers closest to the input terminals of said respective serial connection registers to which the configuration information is input.

11. A configuration method using the reconfigurable circuit according to claim 1, comprising:
a first step of renewing the configuration information of the registers inside one of said multiple serial connection registers using said first connecting means,
a second step of storing the configuration information of the registers inside said serial connection register renewed at said first step into said configuration memories provided for the registers inside said serial connection register,
a third step of duplicating the configuration information stored in the registers inside said serial connection register to the registers inside another serial connection register using said second connecting means, and
a fourth step of storing the configuration information of the registers inside the other serial connection register duplicated at said third step into said configuration memories provided for the registers inside said other serial connection register.

12. A configuration method using the reconfigurable circuit according to claim 1, comprising:
a first step of renewing the configuration information of the registers constituting one of said multiple serial connection registers using said first connecting means,
a second step of duplicating the configuration information stored in part of the registers constituting said one serial connection register to part of the registers constituting another serial connection register using said second connecting means,
a third step of renewing the configuration information of the registers constituting said one serial connection register and the configuration information of the registers constituting said other serial connection register using said first connecting means,
a fourth step of duplicating the configuration information stored in said part of the registers constituting said one serial connection register to said part of the registers constituting said other serial connection register and duplicating the configuration information stored in part of the remaining registers constituting said one serial connection register to part of the remaining registers constituting said other serial connection register using said second connecting means, and
a fifth step of storing the configuration information of the registers inside said one serial connection register into said configuration memories provided for the registers inside said one serial connection register and storing the configuration information of the registers inside said other serial connection register into said configuration memories provided for the registers inside said other serial connection register.

13. A configuration method using the reconfigurable circuit according to claim 7, comprising:
a first step of renewing the configuration information of the registers inside said one serial connection register using said first connecting means,
a second step of duplicating the configuration information stored in said first register to said third register using said second connecting means,
a third step of renewing the configuration information of the registers inside said first serial connection register and the configuration information of the registers inside said second serial connection register using said first connecting means,
a fourth step of duplicating the configuration information stored in said first register to said third register and duplicating the configuration information stored in said fourth register to said second register using said second connecting means, and
a fifth step of storing the configuration information of the registers inside said first serial connection register to said configuration memories provided for the registers inside said first serial connection register and storing the configuration information of the registers inside said second serial connection register to said configuration memories provided for the registers inside said second serial connection register.

14. A configuration method using the reconfigurable circuit according to claim 10, comprising:
a first step of renewing the configuration information of the registers connected to said third connecting means using said third connecting means,
a second step of duplicating the configuration information stored in the registers connected to said third connecting means to all the registers of serial connection registers to which the registers connected to said third connecting means belong, and
a third step of storing the configuration information of the registers inside said configuration chains to said configuration memories.

15. A configuration method using the reconfigurable circuit according to claim 6, comprising:
a first step of storing the configuration information of said configuration memories provided for the registers inside said first serial connection register to the registers inside said first serial connection register,
a second step of duplicating the configuration information stored in the registers inside said first serial connection register to the registers inside said second serial connection register, and
a third step of renewing said configuration information of the registers inside said second serial connection register and outputting said configuration information using said first connecting means.

16. A program for causing a computer to perform the configuration of a reconfigurable circuit equipped with a configuration chain having multiple serial connection registers, has:
operands for providing configuration information to duplicate the configuration information stored in the registers inside one of said multiple serial connection registers constituting said configuration chain to the registers inside another serial connection register constituting said configuration chain and connected in parallel with the registers of said one serial connection register.
